(19) United States
(12) Patent Application Publication
(10) Pub. No.: US 2004/0265749 A1
(43) Pub. Date: Dec. 30, 2004

(54) FABRICATION OF 3D ROUNDED FORMS WITH AN ETCHING TECHNIQUE

(75) Inventors: Marcus Breuer, Dalheim (DD); Hubert Schuy, Oppenheim (DD); Alexandra Welzel, Mainz (DD); Michael Haag, Rodenbach (DD)

Correspondence Address: INTERNATIONAL BUSINESS MACHINES CORPORATION, DEPT. 18G, BLDG. 300-482, 2070 ROUTE 52, HOPEWELL JUNCTION, NY, 12533, US

(73) Assignee: INTERNATIONAL BUSINESS MACHINES CORPORATION, Armonk, NY (US)

(21) Appl. No.: 10/710,186

(22) Filed: Jun. 24, 2004

(30) Foreign Application Priority Data
Jun. 26, 2003 (EP) 03101914.4

(51) Int. Cl. G03F 7/00

(52) U.S. Cl. 430/313; 430/314; 430/328; 430/330

(57) ABSTRACT

Disclosed is a method to build rounded forms on a substrate by means of a masking layer covering at least parts of a substrate by applying the masking layer in a predetermined thickness to the substrate, such that the layer fixedly adheres to the substrate, performing a photo step, developing the masking layer, contracting the masking layer when adhering to the substrate by an irreversible shrinking process with predefined process control parameters, performing the etching process with a shrunk masking layer and etching at least in part through the shrunk masking layer.

### BACKGROUND OF INVENTION

1. Field of the Invention

The present invention relates to the field of material processing, and in particular to fine pattern formation technology by dry etching processes, as is required in many technical fields such as micro-mechanics, semiconductor industry and micro-optics, for example.

2. Description and Disadvantages of Prior Art

In order to make structures or holes with sharp vertical profiles, which are necessary for optimum packing density, usually a dry, anisotropic etching process is used. For example, by exposing a wafer to a plasma (a cloud of energetic ions, electrons, photons, neutral atoms and chemically reactive, free radicals) it is possible to get both a chemical etch component (as in wet etch) and a physical etch component, where energetic ions and neutrals actually knock off bits of the material being etched. The chemical part of the etch is a function of the types of gases that are fed into the plasma, which of course are chosen based on the type of material to be etched (etch applications are broadly separated into silicon, dielectrics and metals). Typically, a chlorine-based chemistry is used for etching polysilicon, suicides and metals, while a fluorine-based chemistry is used for oxide and nitride etching. Etch capabilities are fine-tuned with the addition of argon, hydrogen and/or oxygen.

The benefit of dry etching is that it is relatively easy to tune the system to determine how much chemical and physical etching occurs. At one extreme, it is possible to get only a chemical reaction. This is done by placing the wafer so far away from the plasma that only chemically reactive species reach it. This results in an isotropic etch, but it is quite useful for some applications, such as stripping photoresist. At the other extreme, it is possible to get only a physical component of the etch, by accelerating ions out of the plasma and directing them at the wafer. Ion beam milling is an example of this extreme. This results in a highly anisotropic etch.

Although hard masks are sometimes used (typically a dielectric like SiO₂ or Si₃N₄), the typical mask is photoresist. When a so-called “positive” photoresist is exposed to light (in a lithography tool), polymers in the resist become cross-linked. Areas that were not exposed are not cross-linked and easily dissolved and washed away during a develop step (in negative resists, the areas that were exposed are removed). After etch, the resist is usually removed, so a key challenge for photoresist manufacturers is to make a resist that can stand up well to the etch process (have good etch resistance), yet still be easily stripped after the etch process is over.

Selectivity of the etch process, the ability to etch one material and not another, is also critical. This can be difficult when etching new low-k dielectrics, which can be organic and not very different than the resist itself. This is where hard masks can come into play. Etch selectivity is also critical toward the end of an etch process when the underlying material becomes exposed.

A successful etch is measured by many factors. The main one being if the desired profile is achieved. Prior art etching technique focuses on the high aspect (deep, but not wide) etching.

An exemplary prior art etch process is disclosed in U.S. Pat. No. 5,665,519. A photo resist material is disclosed therein which improves said high aspect etching by providing a chemical amplification type resist material free from deterioration of the resist pattern shape and a decrease in resolution when used in the formation of patterns.

This prior art, which is specialized to produce high resolution, high aspect ratio patterns in a substrate, for example, deep trenches having a small width, will fail, however, when being confronted with the problem of etching rounded forms in the substrate. A need for such rounded forms exists increasingly in many technical fields, for example in a fabrication process of a burnish slider device which is used for producing a very smooth surface of a hard disk, in order to achieve that a magnetic read/write head of the hard disk can be moved in a quite constant, very small distance to the hard disk surface without damaging the surface at protrusion locations, which are protruding too high from the disk plane.

### OBJECTIVES OF THE INVENTION

It is thus an objective of the present invention to provide a method for etching predetermined forms into a substrate by means of a masking layer covering at least parts of said substrate, which is adapted to build inclined or rounded forms in said substrate.

### SUMMARY OF INVENTION

This objective of the invention is achieved by the features stated in the enclosed claims. According to its broadest aspect the present invention discloses a method for etching predetermined forms into a substrate by means of a masking layer covering at least parts of said substrate, comprising the steps of:

a) applying the masking layer in a predetermined thickness to the substrate, such that the layer fixedly adheres to the substrate,

b) performing a photo step,

c) developing the masking layer after said photo step,

d) contracting the masking layer, when adhering to the substrate, by an irreversible shrinking process with predefined process control parameters,

e) performing the etching process with a shrunk masking layer including the step of

f) etching at least in part through the shrunk masking layer.

The resulting advantage is that due to the shrinking process, three dimensionally (3D) inclined or rounded forms of the masking layer are achieved, which are transferred into the substrate by a subsequent etch process, when the etch process is controlled such that the masking layer is etched through at least in part.

In other words, the present invention is directed to the use of an etch process in combination with a structured photo resist in order to design any rounded tips, or more generally any rounded forms or inclined forms in a work piece, which is subjected to prior art etching processing. During a precedent bake process the photo resist gets a special rounded or inclined shape, which is then transferred during a subsequent etch process into the substrate, on which the photo resist is applied.

Thus, the method according to the invention requires a masking layer to be applied to the substrate, onto which the rounded 3D-forms are to applied, which is able to be contracted to a predetermined degree before the actual etching step takes place. During the contracting process the masking layer is irreversibly shrinking in any spatial portions thereof, which do not adhere fixedly to the substrate or to any other non-shrinkable layer to which the masking layer is in contact. Thus, in a simple case, in which the masking layer is usual photo resist material which is applied to the substrate surface, the rest of the surface of the masking layer not fixedly adhering to the substrate will be subjected to the shrinking process. It is the shrinking process itself which actually causes the material to contract. During the contracting the 3D rounded form of sharp tips, etches, etc., being present before the shrinking process are converted into rounded forms.

In order to obtain the rounded forms in the substrate, it is necessary according to the present invention to let the etch process subsequent to the shrinking process penetrate at least partly the masking layer. This means that the etching process must be controlled according to the specific pre-assumptions of work piece geometry, layer thickness, nature of the etching beam, etc., such that the effective etching rate through masking layer and through the substrate can be controlled such that the desired, predetermined geometrical form of the substrate is obtained. Further details of the etching process are given in the specific embodiment detailed further below.

When the masking layer comprises a photo resist material as previously mentioned, the processing of such known materials concerning the etch rates and other process parameters is relatively simple, as the etching of those materials are well known in prior art, at least in so far as a person skilled in the art knows not to exceed predetermined maximum etching times in order to avoid that a photo resist masking layer is completely ablated by the etching beam.

When the shrinking process is achieved by “baking” the photo resist material after being applied to the substrate, for example when using a photo resist material of the type “Clariant AZ 1529”, commercially available by the company Clariant GmbH, 65203 Wiesbaden, Germany, then an easy to control heating process can be used for performing the shrinking process. In this case the irreversibility of the shrinking process is achieved by polymerisation within the photo resist material. It should be noted that other ways also exist to achieve the shrinking process, for example, by exposure to UV-light, or to lower temperatures, or other physical or chemical conditions, as appropriate in relation to the materials in use.

When the etch rates of the photo resist layer and the substrate are controlled by a chemical ion etching process, in which a variable, predetermined portion of fluoride within the etching beam is used, then the etch rates can be controlled selectively by varying the proportion of fluoride within the etching beam. Thus, process control parameters can easily be set in order to obtain any specific rounded form in the substrate. It should be noted, however, that the etching process must be pre-engineered according to the specific pre-assumption in the experimental set up, as it was already mentioned above, and according to the desired geometrical form in the substrate.

The invention can be used advantageously for producing a burnish head usable for fabricating smooth surfaces, for example for hard disks.

### BRIEF DESCRIPTION OF DRAWINGS

The present invention is illustrated by way of example and is not limited by the shape of the figures of the drawings in which:

FIG. 1 is a schematic sectional plan view showing prior art sharp tips of a burnish slider used for producing a smooth hard disk surface,

FIG. 2 is a drawing according to FIG. 1 after using the etching method according to the invention,

FIG. 3 is an enlarged side view of a rounded tip (e.g., view from the right margin of FIG. 2), achieved by a process according to the present invention,

FIG. 4 is a schematic comparison between process steps (top portion) and processed work piece (bottom portion) according to the prior art;

FIG. 5 is a representation according to FIG. 4 illustrating the additional inventive steps of baking the photo resist material;

FIG. 6 is a diagram according to FIG. 4 (bottom portion), illustrating the shrinking of the photo resist during the process step “etch bake” according to the invention;

FIG. 7 is a diagram according to FIG. 4, showing further optional steps of applying a second layer photo resist according to a specific embodiment of the present invention; and

FIG. 8 is a sectional view illustrating a trench in a work piece (e.g. a burnish slider device which is used for producing a very smooth surface of a hard disk device HDD or even a common slider device for carrying a magnetic read/write head in a HDD) having marginal bottom angles of 60 degrees, fabricated according to an embodiment of the present invention.

### DETAILED DESCRIPTION

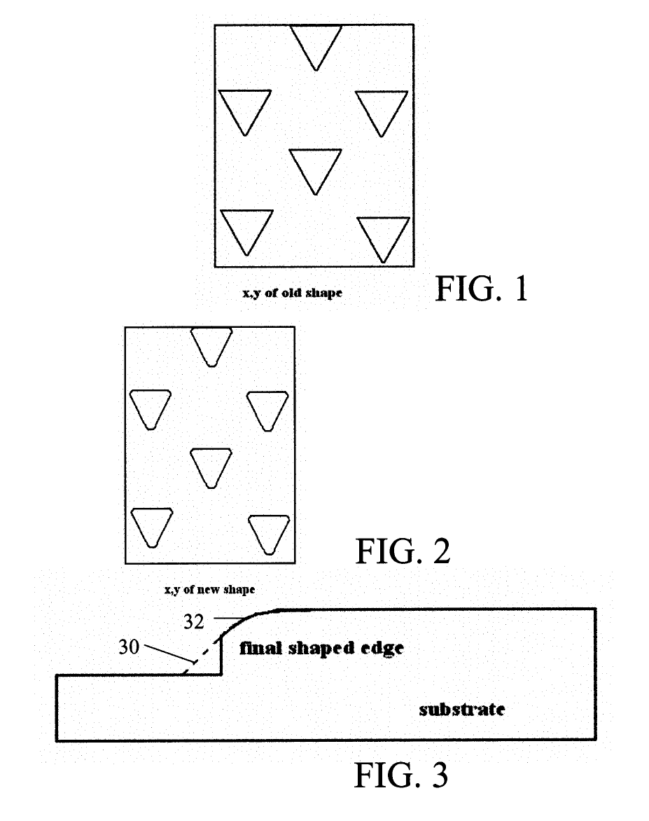

With general reference to the figures and with special reference now to FIG. 1 a slider device is shown comprising a plurality of sharp-tipped triangle-like protrusions, which are used for ablating protruding “hills” from the surface of a hard disk. As shown in the drawing the tips are quite sharp. In particular, in order to produce the sliders the substrate is first polished. The surface is then coated with a photo resist layer and is exposed to a photo step as is known from prior art and afterwards is developed in order to strip the work piece, i.e., remove the photo resist layer from locations where it is not desired.

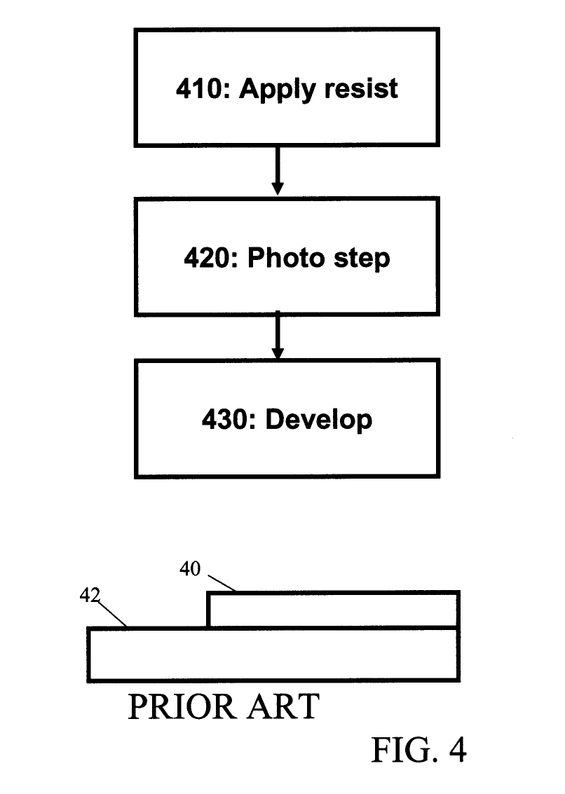

The rounded forms achieved by the method according to the invention are depicted in FIG. 2. With additional reference to FIG. 3 the photo resist layer adhering fixedly to the substrate (prior art) is subjected to a “hard bake” process according to the invention three times for a duration of 105 seconds at a temperature of 130° Celsius. The resist material is Clariant “AZ1529”, as mentioned above. In this heating step the photo resist is stressed such that its edges are shrinking. It should be noted that those portions immediately adjacent to the adhering substrate do not shrink, but instead only “free surface portions” do shrink. The shrinking process results in a rounded shape of the edges seen in the z-direction, as shown in FIG. 3 broken line 30 and portion 32. This is also depicted in a process overview diagram depicted in FIG. 4, in which first the resist material is applied onto the substrate, step 410, which is followed by a photo step 420, and a developing step 430, all prior art, which results in an arrangement depicted schematically on the right portion in FIG. 4 such that a photo resist layer 40 is overlaid and adhering to a substrate layer 42.

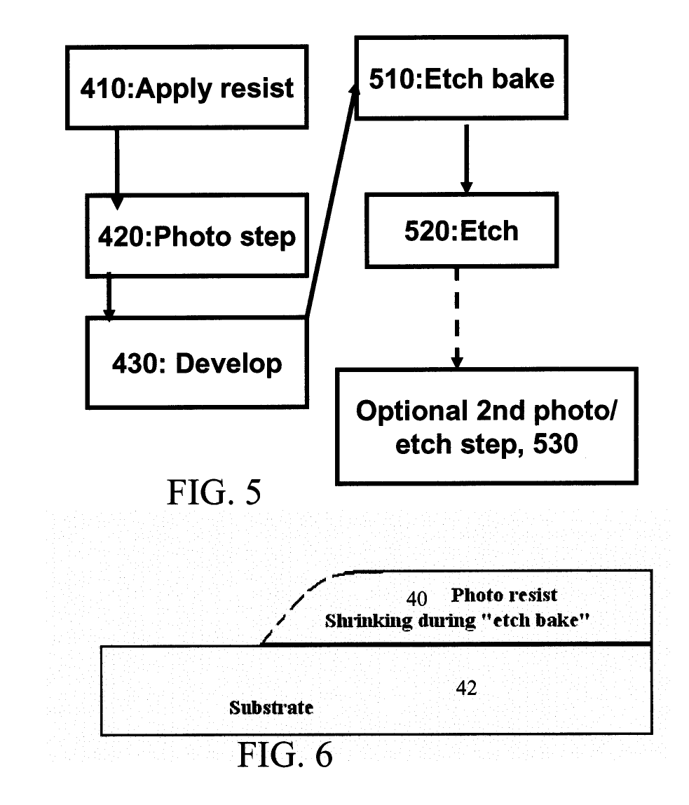

The next step is the baking step according to the invention depicted in FIG. 5 right portion of the figure, step 510. The so-called “etch bake” process 510 should be maintained long enough (e.g., for a duration of 105 seconds at a temperature of 130° Celsius) such that the desired polymerisation process can be preferably completed fully and lead to the desired shrinking process. Thus, as would be appreciated by a person skilled in the art, any control parameters of the baking process must be adapted to the actual properties of the experimental set up given in any particular process situation. The result of the bake process is a photo resist layer having rounded tips or edges at its free surfaces. This is depicted in FIG. 6, showing both layers 40, 42, directly after baking and before beginning the etch process.

Next, a subsequent etching step 520 is applied, for example an ion beam etching process, which transfers the shape of the photo resist, having the rounded forms, to the substrate. This step is denoted with reference sign 520. The transfer of the rounded forms from the photo resist layer into the substrate is explained with reference back to FIG. 3 (broken line shape) as follows.

Assume the etching rate of the substrate is two times larger than the etching rate of the photo resist layer. The etching beam will first penetrate the masking layer portions, which have the smallest thickness. Then gradually, it will penetrate those portions having increasingly larger thickness. Due to the fact that the first penetrated regions expose first the underlying substrate layer, those regions of the substrate layer will be etched with an etching speed which is twice as large compared to the etching speed of the photo resist layer. Thus, a resist ablation front line defining the locations at which the masking layer is fully ablated by the etching process and the substrate is not yet ablated, progresses from left to right in FIG. 3. Thus, as soon as the substrate is exposed to the etching beam, ablation begins in the substrate. The deepest ablation will be found at the left margin of the inclined portion 30 of the substrate, as this is the region of the substrate which is exposed the longest time to the etching beam. Therefore, the geometrical form, i.e. the rounded form of the photo resist layer, is transferred into the underlying substrate layer.

It is important to note that the etching process according to the invention requires an etch process through the resist layer, at least in parts thereof. This is a feature, basically not seen in prior art, which strictly avoids penetrating through the resist layer by the etching process.

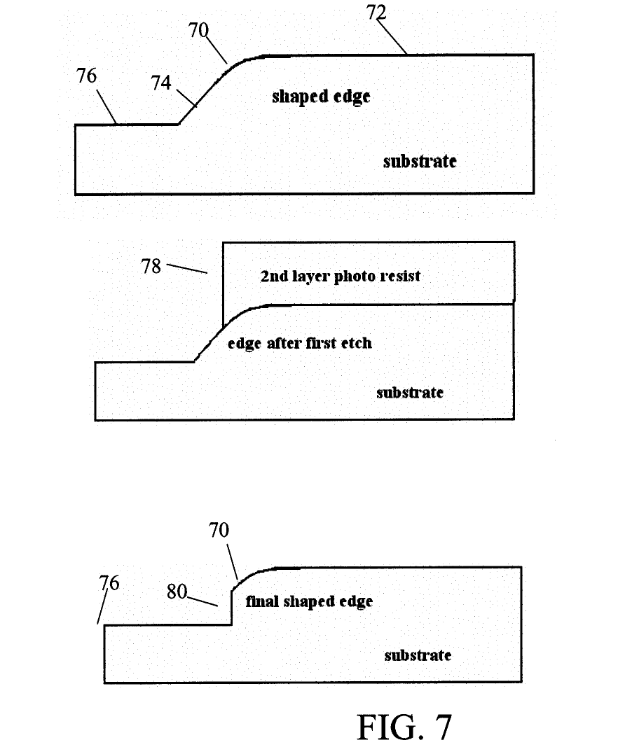

Referring to FIG. 7, the upper part shows the resulting substrate form after the etch process has completed and the masking resist layer was removed by a prior art developing step. The substrate has a rounded transition region denoted with reference sign 70 between a higher level portion 72 and a linearly inclined transition portion 74 leading to a lower level portion 76 which defines, for example, the lowest level of a trench.

Referring now to FIG. 7 the center portion shows a second photo resist layer 78 applied to the substrate as depicted in the top portion of FIG. 7, after the first etching process, described immediately above.

Due to the shallow resist slope, which will also be transferred into the substrate, a second photo/etching step sequence might be necessary, which depends on the desired final design requiring possibly more inclined or vertical parts of walls. The photo resist layer 78 of this second step is thus exemplarily depicted to cover only the top part of the slope, i.e., the rounded transition portion 70 depicted in the upper part of FIG. 7.

The final shaped edge is shown at the bottom portion in FIG. 7, in which the linearly inclined transition portion 74 (see the top part of FIG. 7) is ablated, leading to a vertical wall portion 80 between the bottom of the trench 76 and the rounded transition portion 70.

It should be added that the thickness of the second photo resist layer 78 must be large enough in order to avoid a second etching of transition portion 70.

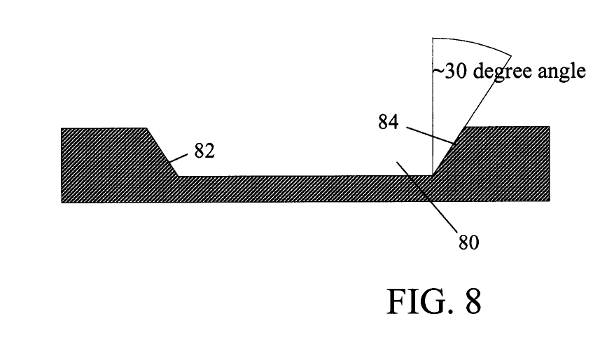

Referring now to FIG. 8 a trench is schematically depicted in a bed 80 of a substrate, e.g., a trench of a burnish slider device which is used for producing a very smooth surface of a hard disk device HDD or a common slider device for carrying a magnetic read/write head in a HDD. Said trench may be assumed to have a depth lower than 14 micrometer, a width of about 600 micrometer (not shown to scale)and is defined laterally by walls 82, 84 being inclined at a degree of 30° (relative to a vertical line), obtained by using the method according to the invention.

In order to do that the above-mentioned principles of processing are applied accordingly in order to obtain a fully extended linearly inclined transition wall between lower and upper level of the trench. As a person skilled in the art may appreciate, such non-vertically inclined walls are basically not possible with prior art etching technique assuming efficient and no cost-intensive production processes. This wall form according to the invention is basically obtainable only by shaping the photo resist layer first, followed by the above-described etching procedure, in which the photo resist layer is at least in part fully penetrated by the etching beam.

It will be apparent to those skilled in the art having regard to this disclosure that other modifications of this invention beyond those embodiments specifically described here may be made without departing from the spirit of the invention. Accordingly, such modifications are considered within the scope of the invention as limited solely by the appended claims.

1. A method for etching predetermined geometrical forms into a substrate by means of a photo resist masking layer covering at least parts of said substrate, comprising the steps of:
a) applying the masking layer in a predetermined thickness to the substrate, such that the masking layer fixedly adheres to the substrate;
b) performing a photo step;
c) developing the masking layer after said photo step;
d) contracting the masking layer, when adhering to the substrate by an irreversible shrinking process with predefined process control parameters;
e) performing an etching process with a shrunk masking layer including the step of etching at least in part through the shrunk masking layer.

2. The method according to claim 1, in which the shrinking process is achieved by baking the photoresist material after being applied to the substrate.

3. The method according to claim 1, in which the irreversible shrinking process is achieved by polymerization of the photoresist material.

4. The method according to claim 1, in which the irreversible shrinking process is achieved by exposing the photoresist material to Ultraviolet light.

5. The method according to claim 1, in which the etch rates of photoresist layer and substrate are controlled by a chemical ion etching process using a variable, predetermined portion of a chemical reactive species within the etching beam.

6. The method according to claim 1, wherein said substrate is a burnish head usable for the treatment of hard disk surfaces.

7. The method according to claim 1, wherein said substrate is a magnetic hard disk device (HDD).

8. 1.The method according to claim 1, wherein said substrate is a optical hard disk device (HDD).

9. The method according to claim 1, wherein said substrate is a slider device for carrying a read/write head of a hard disk device (HDD).
